(19) United States
(12) Patent Application Publication
(10) Pub. No.: US 2009/0243113 A1
(43) Pub. Date: Oct. 1, 2009

(54) Semiconductor structure

(75) Inventors: Derrick Tuten, Scottsdale, AZ (US); David L. Cave, Tempe, AZ (US)

Correspondence Address: KNOBBE MARTENS OLSON & BEAR LLP, 2040 MAIN STREET, FOURTEENTH FLOOR, IRVINE, CA, 92614, US

(73) Assignee: ANDIGILOG, INC., Tempe, AZ (US)

(21) Appl. No.: 12/080,126

(22) Filed: Mar. 31, 2008

(51) Int. Cl. H01L 23/52; H01L 21/4763

(52) U.S. Cl. 257/763; 438/622; 257/E21.495; 257/E23.141

(57) ABSTRACT

A fusible link between metallization layers of a semiconductor device comprises a tungsten plug deposited in a via interconnecting two aluminum metallization layers.

### FIELD OF THE INVENTION

The invention pertains to semiconductor device structures, in general, and to a semiconductor structure having a link between metallization layers that is selectively, permanently openable, in particular.

### BACKGROUND OF THE INVENTION

In the manufacture of some semiconductor devices, it is often desirable to provide the ability to permanently program the device by the use of links that may be permanently opened up. Such links are typically on a single metallization layer of the semiconductor device.

It is often desirable to utilize multilayer metallization paths in semiconductor devices.

It would be desirable to provide a link that may be utilized between metallization layers in semiconductor devices and which may be selectively, permanently opened up.

### SUMMARY OF THE INVENTION

In accordance with the principles of the invention, an openable link is provided for permanently programming connections in a semiconductor device. The openable link is provided between metallization layers of a semiconductor device and comprises a tungsten plug deposited in a via interconnecting two aluminum metallization layers.

A semiconductor device in accordance with the principles of the invention comprises a silicon substrate and a plurality of metal conductor paths separated by silicon dioxide. Each metal conductor paths is in a different plane. A tungsten link is disposed in a via extending through the silicon dioxide and connecting the plurality of metal conductor paths. The tungsten link may be permanently opened thereby opening the electrical connection between the conductor paths by applying a predetermined current level for a predetermined time through the metal conductor paths and tungsten link.

Further in accordance with the principles of the invention, each of the plurality of metal conductor paths comprises aluminum.

A method for providing factory customizable semiconductor devices includes providing fuse links in each semiconductor device. The method comprises the step of: depositing a first metallization layer on the device; depositing one or more insulating layers on the first metallization layer; providing a via in the one or more insulating layers; depositing a tungsten plug in the via; depositing a second metallization layer on the one or more insulating layers. The tungsten plug is in contact with and provides electrical connection between the first and second metallization layers. By applying a predetermined current across the tungsten plug for a predetermined time, the tungsten plug opens up whereby the electrical connection provided by the tungsten plug is permanently opened up.

### BRIEF DESCRIPTION OF THE DRAWING

The invention will be better understood from a reading of the following detailed description of the drawing in which like reference designators are used to identify like elements in the various drawing figures, and in which:

FIG. 1 is a cross-sectional view of a portion of a semiconductor device in accordance with the principles of the invention;

FIG. 2 is the same cross-sectional view of FIG. 1, but showing the effect of applying current to a tungsten link in the semiconductor device; and

FIG. 3 is illustrates the relationship of the time it takes to open a link in accordance with FIG. 1 with respect to maximum current levels through the tungsten link.

### DETAILED DESCRIPTION

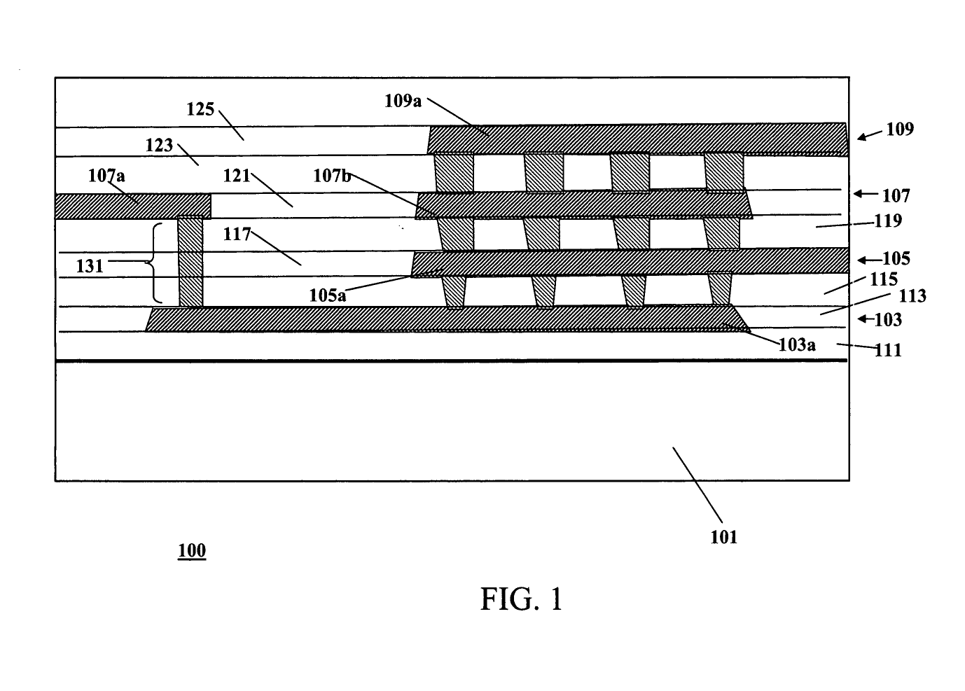

FIG. 1 illustrates a portion of a representative semiconductor device 100 in accordance with the principles of the invention. Device 100 is permanently programmable in accordance with predetermined parameters.

Device 100 includes a silicon substrate 101. Various electronic components are formed on substrate 101 utilizing known manufacturing techniques and processes. Device 100 includes a plurality of insulating silicon dioxide layers 111, 113, 115, 117, 119, 121, 123, 125. There are a plurality of metallization layers 103, 105, 107, 109 formed in the silicon dioxide layers. Each metallization layer may include one or more separate metallization paths such as paths 107a, 107b. Each metallization path in the illustrative embodiment of the invention is aluminum.

To provide for electrical connections between metallization layers, vias are formed in insulating silicon dioxide layers 115, 117, 119, 123 and tungsten plugs are deposited therein. Of particular interest to the present invention is tungsten plug 131.

By applying a relatively large current through tungsten plug or link 131, plug or link 131 acts similarly to a fuse and opens up.

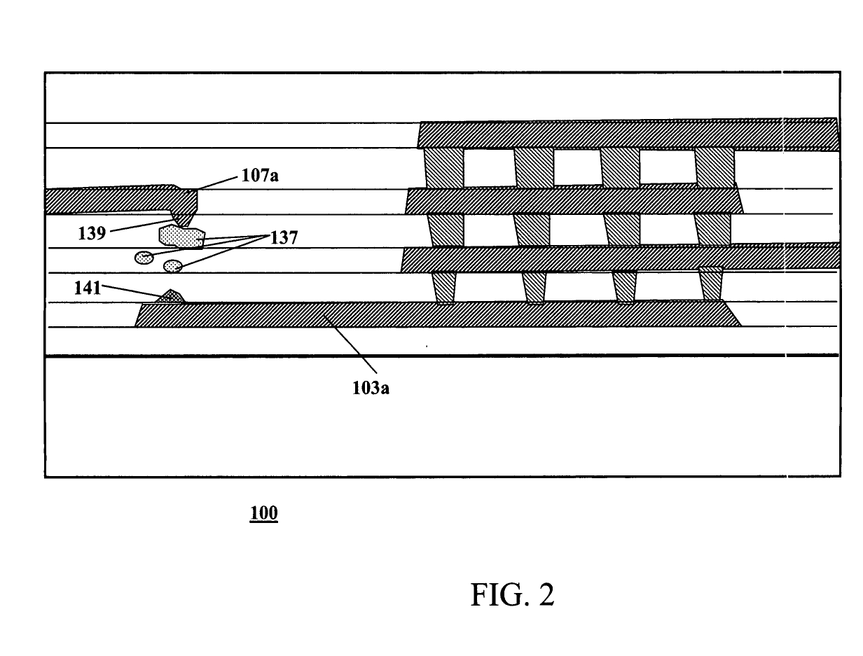

Turning to FIG. 2, the result of the application of link opening electrical current from metallization path 103a to metallization path 107a across tungsten plug 131 is shown. FIG. 2 was obtained from an electron microphotograph of the device 100. The composition of blobs 137, 139, 141 is not known. However, what is known is that the electrical connection between metallization paths 103a to metallization path 107a has been opened.

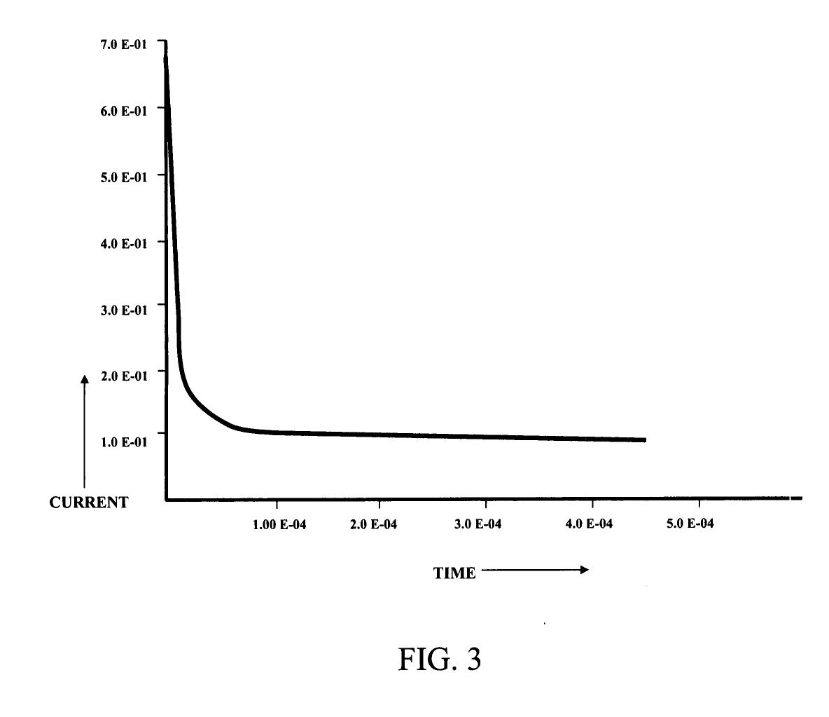

FIG. 3 illustrates the relationship between applying specific maximum current levels across the tungsten plug 131 with the time it takes for the tungsten plug to open breaking the electrical connection between metallization paths in different metallization layers.

The invention has been described in conjunction with a specific illustrative embodiment. It will be understood by those skilled in the art that various changes, substitutions and modifications may be made without departing from the spirit or scope of the invention. It is intended that all such changes, substitutions and modifications be included in the scope of the invention. It is not intended that the invention be limited to the illustrative embodiment shown and described herein. It is intended that the invention be limited only by the claims appended hereto, giving the claims the broadest possible scope and coverage permitted under the law.

1. A semiconductor device, comprising:
a silicon substrate;
a plurality of metal conductor paths separated by silicon dioxide, wherein each of the metal conductor paths is in a different plane; and
a tungsten link disposed through the silicon dioxide and providing an electrical connection between the plurality of metal conductor paths, wherein in response to predetermined maximum current levels being applied for a predetermined time, the tungsten link is configured to permanently open the electrical connection.

2. The semiconductor device of claim 1, wherein each of the plurality of metal conductor paths comprises aluminum.

3. A semiconductor device, comprising:
a plurality of metallization layers;
one or more silicon dioxide layers separating the plurality of metallization layers; and
a tungsten link extending through one or more vias in the one or more silicon dioxide layers to connect at least two metallization layers of the plurality of metallization layers, wherein the tungsten link is configured to function as a programmable fuse link between the at least two metallization layers such that application of a predetermined current for a predetermined time to the at least two metallization layers results in the tungsten link permanently opening up.

4. The semiconductor device of claim 3, wherein each of the plurality of metallization layers comprises aluminum.

5. A method for providing fUsible links in a semiconductor device, the method comprising:
depositing a first metallization layer on the device;
depositing one or more insulating layers on the first metallization layer;
providing a via in the one or more insulating layers;
depositing a tungsten plug in the via; and
depositing a second metallization layer on the one or more insulating layers, such that the tungsten plug is in contact with both the first and second metallization layers;
wherein the tungsten plug is configured to be responsive to a predetermined current being applied across the tungsten plug for a predetermined time by causing-an electrical connection provided by the tungsten plug to permanently open.

6. The method of claim 5, wherein the first and second metallization layers comprise aluminum.

7. The method of claim 6, wherein the one or more insulating layers comprise silicon dioxide.

8. A method of programming a semiconductor device, the method comprising electrically connecting two metallization layers of a semiconductor device with a tungsten plug, wherein the tungsten plug is configured to respond to a predetermined maximum current being applied across the tungsten plug for a predetermined time by causing an electrical connection provided by the plug to open.

9. The method of claim 8, further comprising applying the predetermined maximum current across the tungsten plug to cause the electrical connection provided by the plug to open.

10. The method of claim 8, wherein said electrically connecting comprises deposing the tungsten plug in a via formed though one or more insulating layers that separate the two metallization layers.

11. The method of claim 8, wherein opening the electrical connection provided by the plug permanently programs the semiconductor device.

12. The method of claim 8, wherein the two metallization layers comprise aluminum.

13. The method of claim 9, wherein said applying the predetermined maximum current across the tungsten plug comprises applying current from one of the two metallization paths to the other of the two metallization paths.

14. A semiconductor device, comprising means for electrically connecting two metallization layers of a semiconductor device, wherein the electrically connecting means is configured to respond to a predetermined maximum current being applied across the electrically connecting means for a predetermined time by causing an electrical connection provided by the electrically connecting means to open.

15. The semiconductor device of claim 14, wherein the electrically connecting means comprises a tungsten link.

16. A semiconductor structure, comprising:
a first metallization layer;
a second metallization layer;
one or more insulating layers disposed between the first and second metallization layer; and
a tungsten link electrically connecting the first and second metallization layers, wherein the tungsten link is configured to respond to a predetermined maximum current being applied across the tungsten link for a predetermined time by causing the electrical connection provided by the tungsten link to open.

17. The semiconductor structure of claim 16, wherein the first and second metallization layers comprise aluminum.

18. The semiconductor structure of claim 16, wherein the one or more insulating layers comprise silicon dioxide.

19. The device of claim 1, wherein the tungsten link is disposed within a via between the plurality of metal conductor paths.

20. The device of claim 19, wherein the tungsten link comprises a plug within the via.

21. The device of claim 1, wherein the silicon dioxide is disposed as one or more separation layers separating the plurality of metal conductor paths, wherein each of the one or more separation layers is in a different plane, and wherein the tungsten link is disposed through at least one of the one or more separation layers.

22. The device of claim 21, wherein the electrical connection between the plurality of metal conductor paths comprises a physical contact between the tungsten link and the plurality of metal conductor paths.

23. The device of claim 22, wherein the electrical connection, when open, severs the physical contact between the tungsten link and the plurality of metal conductor paths.

24. The device of claim 22, wherein the electrical connection, when open, severs the tungsten link.

25. The device of claim 1, wherein the predetermined maximum current levels are less than or equal to 700 milliamps.

26. The device of claim 1, wherein the predetermined maximum current levels are applied for less than 100 microseconds.

27. The device of claim 1, wherein application of the predetermined maximum current levels for a predetermined time comprises applying a current which varies in magnitude over time.

28. The device of claim 27, wherein the current decreases over time.

29. The device of claim 27, wherein the current has a high initial magnitude and decreases to a low magnitude.

30. The device of claim 29, wherein the initial high magnitude is maintained for a relatively short period of time.

31. The device of claim 29, wherein the low magnitude is maintained for a relatively long period of time.
